(19) United States
(12) Patent Application Publication
(10) Pub. No.: US 2016/0380167 A1
(43) Pub. Date: Dec. 29, 2016

(54) PRE-CUT SUBSTRATE AND UNIT CHIP SUBSTRATE COMPRISING HEMISPHERICAL CAVITY

(71) Applicant: POINT ENGINEERING CO., LTD., Asan-si (KR)

(72) Inventors: Bum Mo AHN, Yongin-si (KR); Young Woon JEON, Ansan-si (KR); Kyong Su YOO, Seoul (KR)

(21) Appl. No.: 14/753,847

(22) Filed: Jun. 29, 2015

(51) Int. Cl. H01L 33/58; H05K 1/18; H05K 1/02; H01L 33/48; H01L 33/62

(52) U.S. Cl. CPC H01L 33/58; H01L 33/486; H01L 33/62; H05K 1/0298; H05K 1/182

(57) ABSTRACT

Disclosed are an uncut chip plate and a chip substrate. The uncut chip plate includes: conductive portions laminated in one direction to constitute the uncut chip plate; insulation portions alternately laminated with the conductive portions to electrically isolate the conductive portions; and cavities formed at a predetermined depth in a hemispherical concave shape in regions including each of the insulation portions in a corresponding relationship with unit chip substrates defined on an upper surface of the uncut chip plate. According to the present invention, an optical element chip package exhibiting a high illuminance in a central portion can be realized through the use of an easy-to-process planar lens. Furthermore, as compared with a case where a hemispherical lens is used, it is possible to reduce the thickness of the chip package. This makes it possible to reduce the thickness of a device to which the chip package is applied.

### BACKGROUND

1. Technical Field

The present invention relates to an uncut chip plate, a chip substrate and a chip package and, more particularly, to an uncut chip plate including a cavity for mounting a chip.

2. Description of Related Art

In the related art, spaces for mounting chips to an uncut chip plate are formed on the upper surface of the uncut chip plate by mechanical processing or chemical etching. That is to say, Korean Patent No. 10-0986211 discloses a method in which mounting spaces are formed by etching an upper portion of an unprocessed rectangular uncut metal plate. In the case where optical element chips such as UV LEDs or the like are mounted on such an uncut chip plate, spaces having a wide-top/narrow-bottom shape are formed in the uncut chip plate in order to enhance the light reflection performance. After forming the spaces, chips are mounted within the spaces. The spaces are sealed by lenses in order to enhance the light efficiency.

Korean Patent Application Publication No. 10-2010-0122655 discloses a method in which the illuminance in a central portion is increased by forming a hemispherical dome-shaped lens and in which a phosphor contained in a resin material is uniformly dispersed so as to maintain a uniform density and to suppress color unevenness. However, the hemispherical lens disclosed in Korean Patent Application Publication No. 10-2010-0122655 has a problem in that a difficulty is involved in processing the lens.

### SUMMARY

In view of the above technical problem, it is an object of the present invention to provide an uncut chip plate, a chip substrate and a chip package, which are capable of increasing the illuminance in a central portion by using a planar lens.

More specifically, it is an object of the present invention to provide an uncut chip plate, a chip substrate and a chip package, which are capable of, even when a planar lens is used, increasing the illuminance in a central portion by forming a hemispherical cavity.

In accordance with one aspect of the present invention, there is provided an uncut chip plate, including: conductive portions laminated in one direction to constitute the uncut chip plate; insulation portions alternately laminated with the conductive portions to electrically isolate the conductive portions; and cavities formed at a predetermined depth in a hemispherical concave shape in regions including each of the insulation portions in a corresponding relationship with unit chip substrates defined on an upper surface of the uncut chip plate.

The uncut chip plate may further include: auxiliary grooves which are contiguous to surfaces of the cavities and which are formed in a smaller area and a smaller depth than the cavities.

Each of the cavities may have a central portion formed into a flat surface.

The uncut chip plate may further include: bonding portions formed in a recessed shape in the conductive portions existing at the opposite ends of each of the unit chip substrates so as to provide spaces for use in bonding each of the unit chip substrates.

A solder resist may be coated on the upper surface of the uncut chip plate so as to cover regions other than some portions including the bonding portions, the cavities and the auxiliary grooves.

A solder resist may be coated on a lower surface of the uncut chip plate so as to cover regions other than some portions including the bonding portions.

In accordance with another aspect of the present invention, there is provided a chip substrate, including: conductive portions laminated in one direction to constitute the chip substrate; an insulation portion alternately laminated with the conductive portions to electrically isolate the conductive portions; a cavity formed at a predetermined depth in a hemispherical concave shape in a region including the insulation portion on an upper surface of the chip substrate; and bonding portions formed in a recessed shape in the conductive portions existing at the opposite ends of chip substrates so as to provide spaces for use in bonding the chip substrate.

The chip substrate may further include: an auxiliary groove which is contiguous to a surface of the cavity and which is formed in a smaller area and a smaller depth than the cavity.

The cavity may have a central portion formed into a flat surface.

A solder resist may be coated on the upper surface of the chip substrate so as to cover a region other than some portions including the bonding portions, the cavity and the auxiliary groove.

A solder resist may be coated on a lower surface of the chip substrate so as to cover a region other than some portions including the bonding portions.

In accordance with a further aspect of the present invention, there is provided a chip package, including: conductive portions laminated in one direction to constitute an uncut chip plate; insulation portions alternately laminated with the conductive portions to electrically isolate the conductive portions; cavities formed at a predetermined depth in a hemispherical concave shape in regions including each of the insulation portions in a corresponding relationship with unit chip substrates defined on an upper surface of the uncut chip plate; auxiliary grooves which are contiguous to surfaces of the cavities and which are formed in a smaller area and a smaller depth than the cavities; and optical element chips mounted on the conductive portions within the cavities and wire-bonded to cutting surfaces of the auxiliary grooves.

According to the present invention, an optical element chip package exhibiting a high illuminance in a central portion can be realized through the use of an easy-to-process planar lens. Furthermore, as compared with a case where a hemispherical lens is used, it is possible to reduce the thickness of the chip package. This makes it possible to reduce the thickness of a device to which the chip package is applied.

### BRIEF DESCRIPTION OF THE DRAWINGS

FIG. 1 is a perspective view illustrating a chip substrate provided with a hemispherical cavity according to one embodiment of the present invention.

FIG. 2 is a top view of the chip substrate provided with the hemispherical cavity according to one embodiment of the present invention.

FIG. 3 is a rear view of the chip substrate provided with the hemispherical cavity according to one embodiment of the present invention.

FIG. 4 is an explanatory view illustrating a bonding example of the chip substrate provided with the hemispherical cavity according to one embodiment of the present invention.

FIG. 5 is top view of an uncut chip plate provided with hemispherical cavities according to one embodiment of the present invention.

FIG. 6 is a perspective view illustrating a chip substrate provided with a hemispherical cavity according to another embodiment of the present invention.

FIG. 7 is top view of an uncut chip plate provided with hemispherical cavities according to another embodiment of the present invention.

### DETAILED DESCRIPTION OF THE PREFERRED EMBODIMENTS

The following disclosure merely illustrates the principle of the invention. While not explicitly described or illustrated in the subject specification, it may be possible to invent different devices which realize the principle of the invention and which fall within the conception and scope of the invention. Furthermore, all the conditional terms and embodiments disclosed herein are essentially intended to facilitate understanding of the concept of the invention. It is to be understood that the embodiments and states specifically described herein are not limitative.

The above objects, features and advantages will become more apparent from the following detailed descriptions given in conjunction with the accompanying drawings. Thus, a person having an ordinary knowledge in the technical field to which the invention pertains will be able to easily carry out the technical concept of the invention.

In describing the invention, if it is determined that the detailed descriptions on the prior art related to the invention may unnecessarily make obscure the spirit of the invention, the descriptions will be omitted. Hereinafter, detailed description will be given with reference to the accompanying drawings. For the sake of convenience, descriptions will be made by taking an LED as an example of a chip.

In the present embodiment, in order to manufacture an uncut chip plate 10, a plurality of conductive portions 110 having a predetermined thickness and made of an electrically conductive material and a plurality of insulation portions 120 made of an insulating material are bonded to each other and alternately laminated with the insulation portions 120 interposed between the conductive portions 110.

By heating and pressing the conductive portions 110 and the insulation portions 120 in a laminated state, it is possible to manufacture a conductive material lump in which the insulation portions 120 are arranged in a spaced-apart relationship. Then, by vertically cutting the conductive material lump so as to include the insulation portions 120, it is possible to manufacture an uncut chip plate 10 in which a plurality of vertical insulation portions 120 is arranged in a spaced-apart parallel relationship. In the present embodiment, one direction is a vertical direction. The uncut chip plate 10 is manufactured by vertically cutting the conductive material lump along a lamination direction.

The uncut chip plate 10 provided with lens insertion portions according to the present embodiment is manufactured by forming cavities 130 in the uncut chip plate 10 which has been cut in the aforementioned manner.

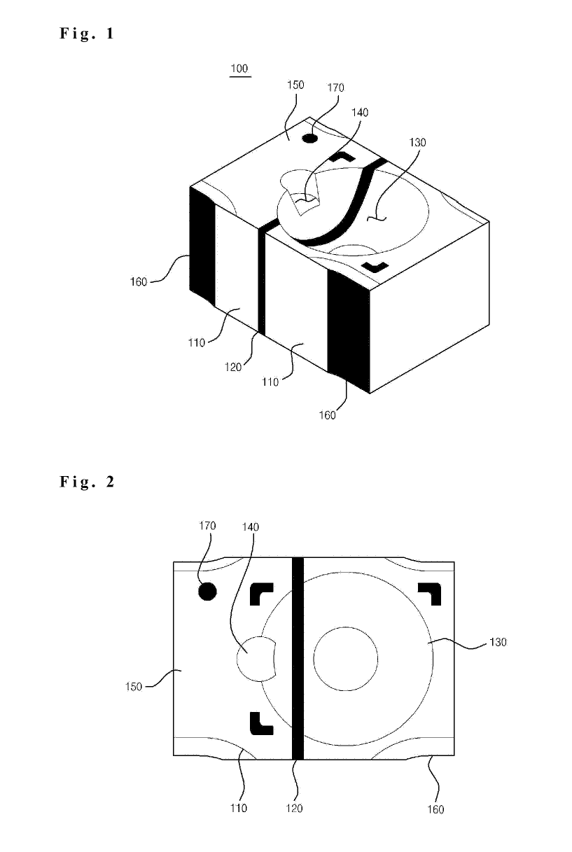

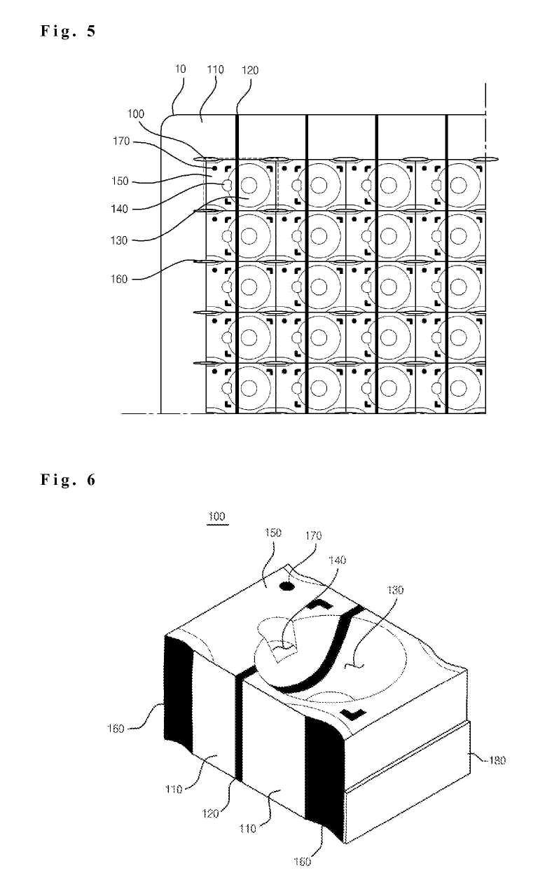

In the present embodiment, the uncut chip plate 10 has a shape illustrated in FIG. 5. A plurality of hemispherical cavities 130 may be formed on the upper surface of the uncut chip plate 10. That is to say, the chip substrate 100 illustrated in FIGS. 1 to 3 is a unit chip substrate and may be manufactured by dicing the uncut chip plate 10 illustrated in FIG. 5.

The chip substrate 100 provided with a hemispherical cavity 130 according to the present embodiment will now be described with reference to FIG. 1.

FIG. 1 is a perspective view illustrating the chip substrate 100 provided with the hemispherical cavity 130 according to one embodiment of the present invention.

Referring to FIG. 1, the chip substrate 100 provided with the hemispherical cavity 130 according to one embodiment of the present invention includes conductive portions 110, an insulation portion 120 and a cavity 130.

That is to say, when the chip substrate 100 according to the present embodiment is seen from above, the hemispherical cavity 130 is formed in the chip substrate 100 so that the cavity 130 is depressed inward. In this case, the hemispherical cavity 130 is formed so as to include the insulation portion 120.

In the present embodiment, the conductive portions 110 are laminated in one direction to constitute the chip substrate 100. The conductive portions 110 serve as electrodes which apply voltages to the chip mounted in a subsequent process. The term “one direction” used herein refers to a lamination direction in which the conductive portions 110 and the insulation portions 120 are alternately laminated in the aforementioned lamination process. As illustrated in FIG. 2, the conductive portions 110 are laminated in the horizontal direction.

The insulation portion 120 is alternately laminated with the conductive portions 110 so as to electrically isolate the conductive portions 110. That is to say, the chip substrate 100 insulated by the insulation portion 120 interposed therebetween may serve as a positive electrode terminal or a negative electrode terminal.

In the present embodiment, there is illustrated an example where one insulation portion 120 exists between two conductive portions 110. However, the chip substrate 100 may be configured by disposing two insulation portions between three conductive portions. Depending on the usage of the chip substrate 100, a larger number of insulation portions may be formed.

As described above, the chip substrate 100 according to the present embodiment may include the cavity 130 formed in a region which includes the insulation portion 120.

In the present embodiment, the cavity 130 is preferably formed in a hemispherical shape. The cavity 130 is configured to enhance the light reflection performance of a mounted chip and is capable of increasing the brightness by focusing light on one point. Thus, when seen in a cross-sectional view, the cavity 130 includes an outer wall having a predetermined curvature.

Furthermore, the cavity 130 includes a central portion preferably formed into a circular flat surface. That is to say, the cavity 130 may include a flat surface so that a chip can be mounted within the cavity 130 without being inclined with respect to the chip substrate 100.

Referring to FIG. 2, the chip substrate 100 provided with the hemispherical cavity 130 according to the present embodiment may further include an auxiliary groove 140. That is to say, in the present embodiment, the auxiliary groove 140 is contiguous to the surface of the cavity 130 and is formed in a smaller area and a smaller depth than the cavity 130.

Specifically, referring to FIG. 1, the auxiliary groove 140 is formed at a depth smaller than that of the cavity 130 and is contiguous to the surface of the cavity 130. Furthermore, the auxiliary groove 140 has a planar cutting surface.

Accordingly, in the case where a chip is mounted within the cavity 130 and the electrode portion of the chip is electrically connected to the conductive portions 110 by wire bonding, one end of a wire is bonded to the electrode portion and the other end of the wire is easily bonded to the planar bottom surface of the auxiliary groove 140.

Referring again to FIG. 2, in the present embodiment, the cross-sectional shape of the auxiliary groove 140 is circular. However, depending on the design choice, the cross-sectional shape of the auxiliary groove 140 may be changed to a rectangular shape, an elliptical shape or other shapes. Furthermore, the depth of the auxiliary groove 140 is set such that the brightness increase in the hemispherical cavity 130 is not hindered.

In FIGS. 1 and 2, there is illustrated an example in which only one cavity 130 is formed. However, depending on the usage of the chip substrate 100, it may be possible to form a plurality of cavities. For example, four cavities may be formed. In this case, two insulation portions may be disposed.

Referring to FIGS. 1 and 2, the chip substrate 100 according to the present embodiment further includes spaces for use in bonding the chip substrate 100, namely bonding portions 160 formed in a concave shape in the conductive portions 110 existing at the opposite ends of the chip substrate 100. Specifically, referring to FIG. 4, if the chip substrate 100 is bonded to a printed circuit board 200 by soldering, the conductive portions 110 existing at the opposite ends of the chip substrate 100 may be formed in a concave shape so as to provide spaces in which solders 50 are accommodated.

In the present embodiment, there is illustrated an example where the conductive portions 110 are formed at four corners of the chip substrate 100. However, this is merely for the purpose of convenience in the manufacturing process of the chip substrate 100 which is formed by cutting the uncut chip plate 10. In view of the bonding process illustrated in FIG. 4, only two bonding portions 160 may be formed at two of the four corners of the chip substrate 100. On this point, descriptions will be made later with reference to FIG. 5.

The bonding portions 160 are formed in an inwardly recessed shape so as to provide spaces in which solders are disposed. The shape and size of the bonding portions 160 may vary depending on the design thereof.

The bonding portions 160 of the chip substrate 100 according to the present embodiment may be formed in such a shape that the width thereof grows smaller outward. That is to say, as illustrated in FIG. 2, the spaces defining the bonding portions 160 may become narrower rather than wider toward the ends of the chip substrate 100. This is to make sure that the solders coated on the bonding portions 160 are stably kept in place without moving outward.

Referring to FIG. 6, a chip substrate 100 according to another embodiment of the present invention may include stopper portions 180 which are formed in the lower portions of the opposite end surfaces of the conductive portions 110 to prevent outward flow of the solders coated on the bonding portions 160.

In FIG. 6, the stopper portions 180 partially protrude from the lower portions of the opposite end surfaces of the conductive portions 110. Accordingly, if the amount of solders is larger than a suitable amount, the solders flow out toward the regions other than the stopper portions 180. Thus, the amount of solders directly bonded to a printed circuit board becomes uniform. This makes it possible to prevent a chip package from being tilted during the course of soldering.

Accordingly, it is possible to stably perform the soldering process, thereby preventing generation of bonding defects and enhancing the productivity and the quality of a chip package.

Furthermore, a solder resist 150 may be coated on the upper surface of the chip substrate 100 including the hemispherical cavity 130 so as to cover a region other than the bonding portions 160, the cavity 130 and the auxiliary groove 140.

When the chip substrate 100 is bonded to the printed circuit board 200 by soldering, the solder resist 150 prevents the solders 50 from spreading over the upper surface of the chip substrate 100 beyond the bonding portions 160. This makes it possible to prevent generation of defects such as dielectric breakdown and the like.

Referring again to FIGS. 1 and 2, in the present embodiment, the solder resist 150 is formed on the upper surface of the chip substrate 100 so that the solder resist 150 is recessed inward from the bonding portions 160. This allows the solders to be formed in some regions of the upper surface of the chip substrate 100 near the bonding portions 160. It is therefore possible to widen the soldered area and to assure strong bonding when the chip substrate 100 is bonded to the printed circuit board 300 as illustrated in FIG. 4.

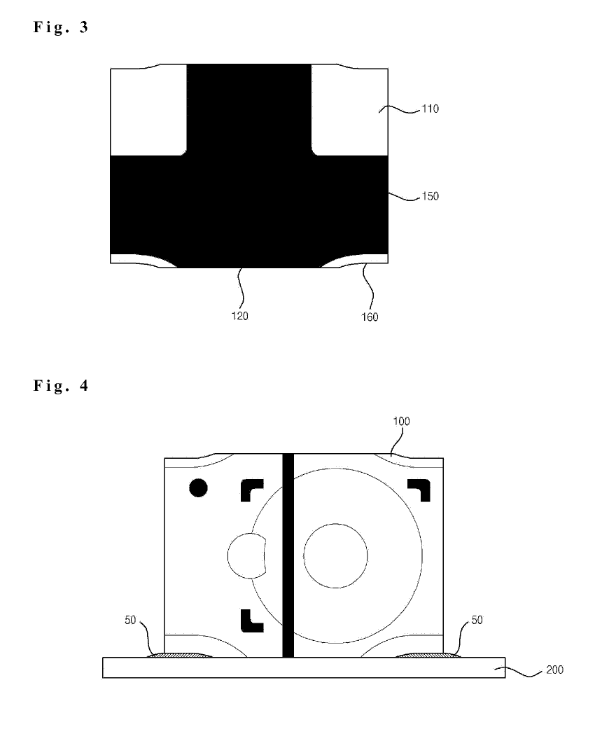

Similarly, as illustrated in FIG. 3, a solder resist 150 may be coated on the lower surface of the chip substrate 100 including the hemispherical cavity 130 so as to cover a region other than the bonding portions 160 of the chip substrate 100.

More specifically, as illustrated in FIGS. 1 and 2, the solder resist 150 is formed on the lower surface of the chip substrate 100 so that the solder resist 150 is recessed inward from the bonding portions 160. This allows the solders to be formed in some regions of the lower surface of the chip substrate 100 near the bonding portions 160. It is therefore possible to widen the soldered area and to assure strong bonding when the chip substrate 100 is bonded to the printed circuit board 200 as illustrated in FIG. 4.

Furthermore, the chip substrate 100 including the hemispherical cavity 130 according to the present embodiment may include an electrode indication portion 170.

Referring again to FIG. 1, as described above, in the chip substrate 100 according to the present embodiment, the insulation portion 120 is interposed between two conductive portions 110. Voltages of opposite polarities may be applied to the respective conductive portions 110 isolated by the insulation portion 120. Accordingly, if a mark is formed on the surface of one of the conductive portions 110 and if it is promised in advance that, for example, a positive voltage is applied to one of the conductive portions 110 having the mark, a user can easily determine the polarity of each of the conductive portions 110.

An uncut chip plate 10 including hemispherical cavities 130 according to one embodiment of the present invention will now be described with reference to FIG. 5.

The uncut chip plate 10 including hemispherical cavities 130 according to the present invention includes conductive portions 110, insulation portions 120, cavities 130 and auxiliary grooves 140.

More specifically, the chip substrate 100 including the hemispherical cavity 130 according to the aforementioned embodiment is obtained by cutting the uncut chip plate 10 illustrated in FIG. 5 into unit chip substrates having a predetermined size. For that reason, the conductive portions 110, the insulation portions 120 and the cavities 130 of the uncut chip plate 10 according to the present embodiment perform the functions described in the aforementioned embodiment.

The conductive portions 110 are laminated in one direction to constitute the uncut chip plate 10. The insulation portions 120 are alternately laminated with the conductive portions 110 to electrically isolate the conductive portions 110.

The cavities 130 are formed in the respective chip substrates 100 defined on the upper surface of the uncut chip plate 10. In the regions including each of the insulation portions 120, the cavities 130 are formed at a predetermined depth in a hemispherical concave shape.

Solder resists 150 are coated on the upper surface of the uncut chip plate 10 including the hemispherical cavities 130 so as to cover regions other than at least some portions of the corners of the respective unit chip substrates 100, the cavities 130 and the auxiliary grooves 140. Furthermore, solder resists 150 are coated on the lower surface of the uncut chip plate 10 including the hemispherical cavities 130 so as to cover regions other than the bonding portions 160 of the respective unit chip substrates 100.

Referring again to FIG. 5, the uncut chip plate 10 according to the present embodiment further includes bonding portions 160. The bonding portions 160 are formed to penetrate the conductive portions 110 of the uncut chip plate 10. As described in the aforementioned embodiment, the through-holes for defining the bonding portions 160 are formed to provide spaces in which the solders 50 are disposed when the chip substrate 100 severed from the uncut chip plate 10 is bonded to the printed circuit board 200 by soldering. The through-holes may be formed in an elliptical shape or other shapes so that the end portions of the conductive portions 110 have a concave shape.

The shape of the through-holes may be changed to a rectangular shape, a circular shape or other shapes as long as the through-holes can provide concave spaces in the respective chip substrates 100 severed from the uncut chip plate 10.

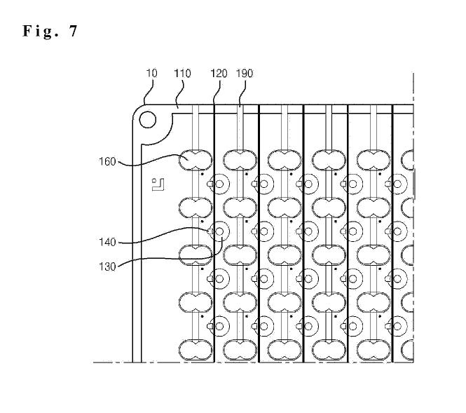

Alternatively, the uncut chip plate 10 may be formed to have a configuration illustrated in FIG. 7.

More specifically, unlike the configuration illustrated in FIG. 5, through-holes having a substantially 8-like shape may be formed in the uncut chip plate 10 so that the bonding portions 160 of the respective chip substrates 100 have a width which grows smaller outward.

In order to form the stopper portions 180 illustrated in FIG. 6, linear grooves 190 having a predetermined depth and a predetermined width may be formed in the uncut chip plate 10 in view of the cutting lines of the respective chip substrates 100. In this case, if the uncut chip plate 10 illustrated in FIG. 7 is cut, it is possible to manufacture unit chip substrates each having the stopper portions 180 illustrated in FIG. 6.

According to the present invention described above, an optical element chip package exhibiting a high illuminance in a central portion may be realized by using an easy-to-process planar lens rather than a hemispherical lens so that a phosphor is uniformly dispersed in a resin material. Furthermore, the thickness of the chip package may be reduced as compared with a case where a hemispherical lens is used. This makes it possible to reduce the thickness of a device to which the chip package is applied.

While not shown in the drawings, when packaging an optical element chip using the chip substrate 100 according to the embodiment described above, the optical element chip is mounted on one of the conductive portions 110 within the cavity 130 having a hemispherical concave shape. The optical element chip is wire-bonded to the bottom surface of the auxiliary groove 140.

That is to say, the application of voltages to the optical element chip may be realized through the wire bonding or the bonding to the conductive portions 110. It goes without saying that the voltage application method may be differently changed depending on the structure of a mounted chip.

The forgoing descriptions are mere illustration of the technical concept of the present invention. A person having an ordinary knowledge in the technical field to which the invention pertains will be able to make modifications, changes and substitutions without departing from the essential features of the invention.

Accordingly, the embodiments and the accompanying drawings disclosed herein are not intended to limit the technical concept of the present invention but are intended to describe the present invention. The technical concept of the present invention shall not be limited by the embodiments and the accompanying drawings. The protection scope of the present invention shall be construed on the basis of the appended claims. All the technical concepts which are equivalent in scope to the claims shall be construed to fall within the scope of the present invention.

1. An uncut chip plate, comprising:
conductive portions laminated in one direction to constitute the uncut chip plate;
insulation portions alternately laminated with the conductive portions to electrically isolate the conductive portions; and
cavities formed at a predetermined depth in a hemispherical concave shape in regions including each of the insulation portions in a corresponding relationship with unit chip substrates defined on an upper surface of the uncut chip plate,
wherein the insulation portions are exposed on inner side surfaces of the cavities higher than bottom surfaces of the cavities without being exposed at the bottom surfaces of the cavities.

2. The uncut chip plate of claim 1, further comprising:
auxiliary grooves which are contiguous to surfaces of the cavities and which are formed in a smaller area and a smaller depth than the cavities.

3. The uncut chip plate of claim 1, wherein each of the cavities has a central portion formed into a flat surface.

4. The uncut chip plate of claim 2, wherein each unit chip substrate extends from one of the conductive portions at one end of the unit chip substrate to one of the conductive portions at an opposite end of the unit chip substrate with one of the insulation portions located in between the two ends of the unit chip substrate, the uncut chip plate further comprising:
bonding portions formed in a recessed shape in the conductive portions existing at both ends of each of the unit chip substrates so as to provide spaces for use in bonding each of the unit chip substrates.

5. The uncut chip plate of claim 4, wherein a solder resist is coated on the upper surface of the uncut chip plate so as to cover regions other than some portions including the bonding portions, the cavities and the auxiliary grooves.

6. The uncut chip plate of claim 4, wherein a solder resist is coated on a lower surface of the uncut chip plate so as to cover regions other than some portions including the bonding portions.

7. The uncut chip plate of claim 1, wherein linear grooves having a predetermined width and a predetermined depth are formed in regions which include cutting lines of the unit chip substrates defined on the upper surface of the uncut chip plate.

8. A chip substrate, comprising:
conductive portions laminated in one direction to constitute the chip substrate;
an insulation portion alternately laminated with the conductive portions to electrically isolate the conductive portions;
a cavity formed at a predetermined depth in a hemispherical concave shape in a region including the insulation portion on an upper surface of the chip substrate; and
bonding portions formed in a recessed shape in the conductive portions of the chip substrate so as to provide spaces for use in bonding the chip substrate,
wherein the insulation portion is exposed on an inner side surface of the cavity higher than a bottom surface of the cavity without being exposed at the bottom surface of the cavity.

9. The chip substrate of claim 8, further comprising:
an auxiliary groove which is contiguous to a surface of the cavity and which is formed in a smaller area and a smaller depth than the cavity.

10. The chip substrate of claim 8, wherein the cavity has a central portion formed into a flat surface.

11. The chip substrate of claim 9, wherein a solder resist is coated on the upper surface of the chip substrate so as to cover a region other than some portions including the bonding portions, the cavity and the auxiliary groove.

12. The chip substrate of claim 9, wherein a solder resist is coated on a lower surface of the chip substrate so as to cover a region other than some portions including the bonding portions.

13. The chip substrate of claim 8, wherein stopper portions having a predetermined thickness and a predetermined height are formed in lower portions of the opposite end surfaces of the conductive portions.

14. A chip package, comprising:
conductive portions laminated in one direction to constitute an uncut chip plate;
insulation portions alternately laminated with the conductive portions to electrically isolate the conductive portions;
cavities formed at a predetermined depth in a hemispherical concave shape in regions including each of the insulation portions in a corresponding relationship with unit chip substrates defined on an upper surface of the uncut chip plate;
auxiliary grooves which are contiguous to surfaces of the cavities and which are formed in a smaller area and a smaller depth than the cavities; and
optical element chips mounted on the conductive portions within the cavities and wire-bonded to bottom surfaces of the auxiliary grooves,
wherein the insulation portions are exposed on inner side surfaces of the cavities higher than bottom surfaces of the cavities without being exposed at the bottom surfaces of the cavities.
